(19) United States
(12) Patent Application Publication
(10) Pub. No.: US 2016/0379707 A1
(43) Pub. Date: Dec. 29, 2016

(54) CROSS POINT MEMORY DEVICE

(71) Applicant: RESEARCH & BUSINESS FOUNDATION SUNGKYUNKWAN UNIVERSITY, Suwon-si (KR)

(72) Inventors: Joon Sung YANG, Seongnam-si (KR); Hyunseung HAN, Seoul (KR)

(73) Assignee: RESEARCH & BUSINESS FOUNDATION SUNGKYUNKWAN UNIVERSITY, Suwon-si (KR)

(21) Appl. No.: 15/191,983

(22) Filed: Jun. 24, 2016

(30) Foreign Application Priority Data
Jun. 25, 2015 (KR) 10-2015-0090378
Jun. 25, 2015 (KR) 10-2015-0090379
Jun. 25, 2015 (KR) 10-2015-0090380

(51) Int. Cl. G11C 13/00

(52) U.S. Cl. CPC G11C 13/004; G11C 13/0069

(57) ABSTRACT

Provided is a cross-point memory device including multiple word lines arranged in parallel with each other, multiple bit lines arranged to be orthogonal to the word lines and parallel with each other, and multiple cross-point memory cells electrically connected between the word lines and the bit lines, respectively. Herein, a cross-sectional area of a cross-section perpendicular to a longitudinal direction of the bit lines is formed to be increased as being farther from a first end of the bit lines.

### CROSS-REFERENCE TO RELATED APPLICATIONS

This application claims the benefit under 35 USC 119(a) of Korean Patent Applications Nos. 10-2015-0090378, 10-2015-0090379 and 10-2015-0090380 filed in the Korean Intellectual Property Office on Jun. 25, 2015, the entire disclosure of which is incorporated herein by reference for all purposes.

### BACKGROUND

1. Field

The following description relates to a cross-point memory device in which a cross-sectional area of a metallic line is adjusted.

2. Description of Related Art

A cross-point memory cell is located between two sets of conductors disposed on and under the memory cell and extended in an orthogonal direction thereto. A first set of conductors located under the memory cell may be referred to as a bit line, and a second set of conductors located on the memory cell may be referred to as a word line. That is, each memory cell in each cross-point memory array is located at a cross-point between a word line and a bit line. When one of memory cells in an array is selected to read or write the memory cell, it is necessary to activate a word line and a bit line involved in the memory cell. When the selected memory cell is read, it is necessary to apply a voltage to the word line and measure a resultant current passing through the selected memory cell.

In particular, memories to which a cross-point memory structure is applied are mainly resistance-controlled memories such as phase change memory (PCM) and memristor. Such memories can be used as multi-level cells (MLC) due to their constant cell state. In this case, however, delicate read/write processes are needed, and, thus, it is necessary to precisely adjust a voltage level and a signal width during the read and write processes.

In this regard, Korean Patent Laid-open Publication No. 10-2014-0126503 (entitled “Semiconductor apparatus”) discloses a semiconductor apparatus which includes first conductive patterns respectively coupled to a common source and selection lines of a memory block formed at a substrate, second conductive patterns configured to form a bit line coupled to the memory block, and third conductive patterns configured to transmit a block selection signal to couple local lines of the memory block to global lines and in which the first to third conductive patterns are arranged in different layers over the memory block.

Meanwhile, a metallic line used in a semiconductor has the resistivity. The resistivity is in reverse proportion to the cross-sectional area and in proportion to the length. Therefore, the resistivity of the metallic line may cause a problem within the semiconductor. For example, a cell far from a row decoder and a write driver in a memory structure may be applied with a low bias voltage due to a voltage drop caused by a high resistivity of a long metallic line.

Further, a cell far from a controller may have a slow response time caused by a delay time occurring in a metallic line.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In view of the foregoing, the present disclosure provides a method for minimizing a difference in voltage drop and a difference in delay time occurring in a metallic line in a cross-point memory device by adjusting a cross-sectional area of the metallic line.

However, problems to be solved by the present disclosure are not limited to the above-described problems. There may be other problems to be solved by the present disclosure.

In a first aspect, a cross-point memory device includes multiple first data lines arranged in parallel with each other, multiple second data lines arranged to intersect with the first data lines and arranged in parallel with each other, and multiple cross-point memory cells electrically connected between the first data lines and the second data lines, respectively. Herein, the first data line spaced away by a first distance from an end of the first data lines has a different cross-sectional area from the first data line spaced away by a second distance from the end of the first data lines.

In a second aspect, a cross-point memory device includes multiple first data lines arranged in parallel with each other, multiple second data lines arranged to intersect with the first data lines and arranged in parallel with each other, and multiple cross-point memory cells electrically connected between the first data lines and the second data lines, respectively. Herein, the second data line intersecting with an n^{th} (n is a natural number) data line of the first data lines has a different cross-sectional area from the second data line intersecting with an m^{th} (m is a natural number) data line of the first data lines.

According to the present disclosure, the cross-point memory device can solve the problem of a low bias voltage applied due to a high voltage drop by adjusting a cross-sectional area of a metallic line using the resistivity of the metallic line which is in reverse proportion to the cross-sectional area and in proportion to the length. Accordingly, the cross-point memory device can minimize a difference in delay time of an electric signal. Other features and aspects will be apparent from the following detailed description, the drawings, and the claims.

### BRIEF DESCRIPTION OF THE DRAWINGS

FIG. 1A and FIG. 1B are configuration views of a general cross-point memory device.

FIG. 2 is a configuration view of a cross-point memory device in accordance with an exemplary embodiment of the present disclosure.

FIG. 3A to FIG. 3C are perspective views of a cross-point memory cell in accordance with an exemplary embodiment of the present disclosure.

FIG. 4 is an exemplary diagram of a cross-point memory device in accordance with another exemplary embodiment of the present disclosure.

FIG. 5 is an exemplary diagram of a cross-point memory device in accordance with another exemplary embodiment of the present disclosure.

FIG. 6 is a flowchart showing a method of manufacturing a cross-point memory device in accordance with an exemplary embodiment of the present disclosure.

FIG. 7A and FIG. 7B are exemplary diagrams illustrating components of a cross-point memory device in accordance with another exemplary embodiment of the present disclosure.

FIG. 8 is an exemplary diagram of a cross-point memory device in accordance with another exemplary embodiment of the present disclosure.

FIG. 9 is an exemplary diagram of a cross-point memory device in accordance with another exemplary embodiment of the present disclosure.

FIG. 10A and FIG. 10B are configuration views of a cross-point memory device in accordance with another exemplary embodiment of the present disclosure.

FIG. 11 is a flowchart showing a method of manufacturing a cross-point memory device in accordance with another exemplary embodiment of the present disclosure.

FIG. 12 is a configuration view of a cross-point memory device in accordance with another exemplary embodiment of the present disclosure.

FIG. 13A to FIG. 13C are perspective views of a cross-point memory cell in accordance with another exemplary embodiment of the present disclosure.

FIG. 14 is an exemplary diagram of a cross-point memory device in accordance with another exemplary embodiment of the present disclosure.

FIG. 15 is an exemplary diagram of a cross-point memory device in accordance with another exemplary embodiment of the present disclosure.

FIG. 16 is a flowchart showing a method of manufacturing a cross-point memory device in accordance with another exemplary embodiment of the present disclosure.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness. The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. Hereinafter, embodiments of the present disclosure will be described in detail with reference to the accompanying drawings so that the present disclosure may be readily implemented by those skilled in the art. However, it is to be noted that the present disclosure is not limited to the embodiments but can be embodied in various other ways. In drawings, parts irrelevant to the description are omitted for simplicity of explanation, and like reference numerals denote like parts through the whole document.

Through the whole document, the term “connected to” or “coupled to” that is used to designate a connection or coupling of one element to another element includes both a case that an element is “directly connected or coupled to” another element and a case that an element is “electronically connected or coupled to” another element via still another element. Further, through the whole document, the term “comprises or includes” and/or “comprising or including” used in the document means that one or more other components, steps, operation and/or existence or addition of elements are not excluded in addition to the described components, steps, operation and/or elements unless context dictates otherwise.

The following exemplary embodiments are provided only for understanding of the present disclosure but not intended to limit the right scope of the present disclosure. Therefore, the inventions that perform the same functions in the same scope as the present disclosure are also included in the right scope of the present disclosure.

Prior to detailed description, a cross-point memory cell will be explained. In many cases, the cross-point memory cell is implemented in the form of an array, and the cross-point memory cell typically includes a select device such as a transistor configured to suppress an influence of a leakage current passing through a non-selected memory cell on reading or writing of a selected memory cell. For example, the transistor may be located between a word line and a bit line in series with a memory cell in order to provide isolation by switching off a non-selected device through a control gate (used as a controller in the present specification).

Meanwhile, the cross-point memory cell array includes multiple first data lines and second data lines intersecting with each other and also includes multiple memory cells formed at the respective cross-points. Herein, the first data lines and the second data lines are word lines or bit lines. If the first data lines are word lines, the second data lines are bit lines, and if the first data lines are bit lines, the second data lines are word lines. In the following, examples of bit lines and word lines will be suggested directly for convenience in explanation.

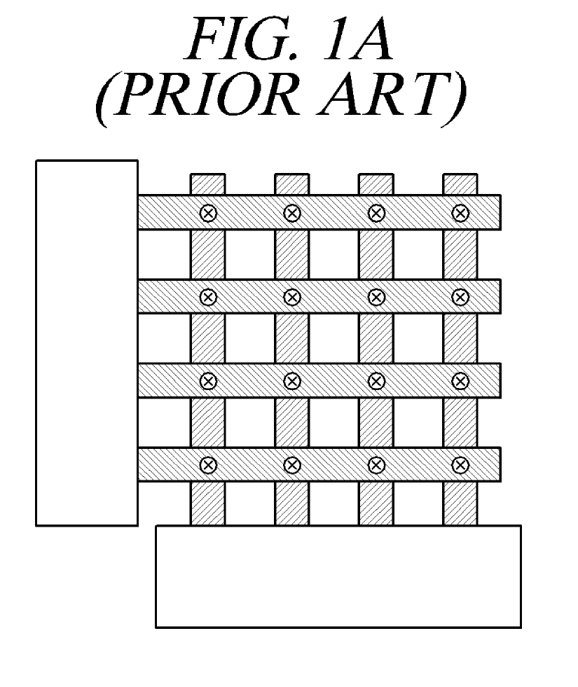

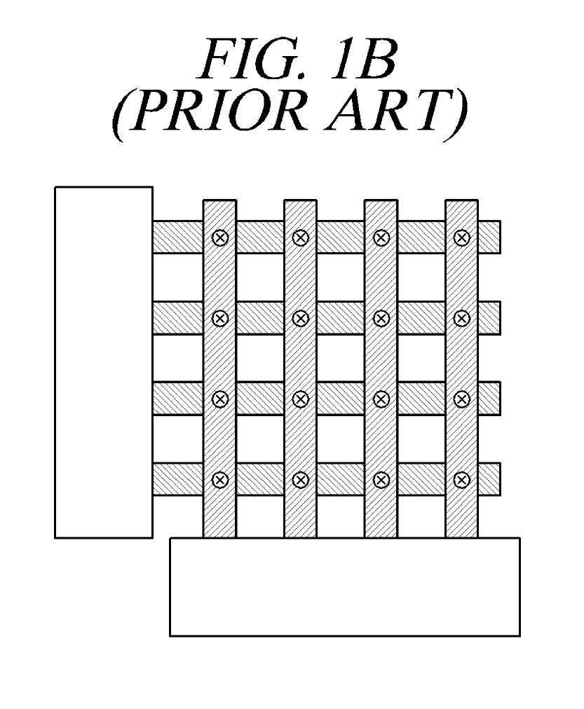

FIG. 1A and FIG. 1B provide configuration views of a general cross-point memory device.

Referring to FIG. 1A and FIG. 1B, the general cross-point memory device may include word lines, bit lines, a first controller, a second controller, and a memory cell. Typically, in a memory cell array, n number of word lines and m number of bit lines for selective data input/output intersect with each other at right angles. That is, the memory has a structure in which word lines and bit lines form a lattice shape by intersecting with each other, and the memory is operated by calling a memory cell at a cross-point between specific word line and bit line. This combination called a unit memory cell is a basic bit for data storage. Therefore, an N×M cell array includes N×M number of memory bits, which determines an integrated capacity of a memory device.

The word lines are actually used to read and write data and may be extended in a first direction. The bit lines function to transfer a charge into the memory device or read the transferred charge and may be extended in a second direction perpendicular to the word line.

Further, the first controller is connected to word lines and may be arranged at a first end of the bit lines. The second controller is connected to the bit lines and may be arranged at a first end of the word lines. These controllers are configured as circuits located at an edge of the memory cell array and configured to supply a voltage or current required for data input/output.

Further, in this memory structure, the word lines may be typically located on top (FIG. 1A) or the bit lines may be located on top (FIG. 1B).

Meanwhile, a metallic line used in a semiconductor has the resistivity. The resistivity is in reverse proportion to the cross-sectional area and in proportion to the length. Therefore, the resistivity of the metallic line may cause a problem within the semiconductor. For example, a cell far from a row decoder and a write driver in a memory structure may be applied with a low bias voltage due to a voltage drop caused by a high resistivity of a long metallic line.

Further, a cell far from a controller may have a slow response time caused by a delay time occurring in a metallic line.

According to the present disclosure, it is possible to uniformly distribute a resistivity value applied to a cross-point memory cell array using a resistivity value of metal which is in reverse proportion to the cross-sectional area and in proportion to the length. Further, it is possible to solve a slow response time caused by a delay time. Typically, in a memory cell far from a controller, a high voltage drop occurs. A cross-point memory device in accordance with an exemplary embodiment of the present disclosure can uniformly distribute a voltage drop value by increasing cross-sectional areas of a word line and a bit line connected to a memory cell far from a controller.

Hereinafter, a cross-point memory device suggested by the present disclosure will be described in detail with reference to the accompanying drawings.

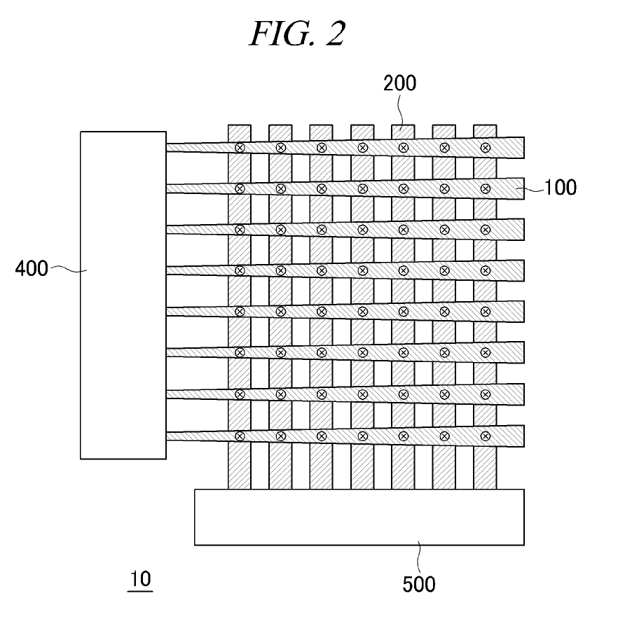

FIG. 2 is a configuration view of a cross-point memory device in accordance with an exemplary embodiment of the present disclosure.

A cross-point memory device 10 in accordance with an exemplary embodiment of the present disclosure may include word lines 100, bit lines 200, cross-point memory cells 300, a first controller 400, and a second controller 500.

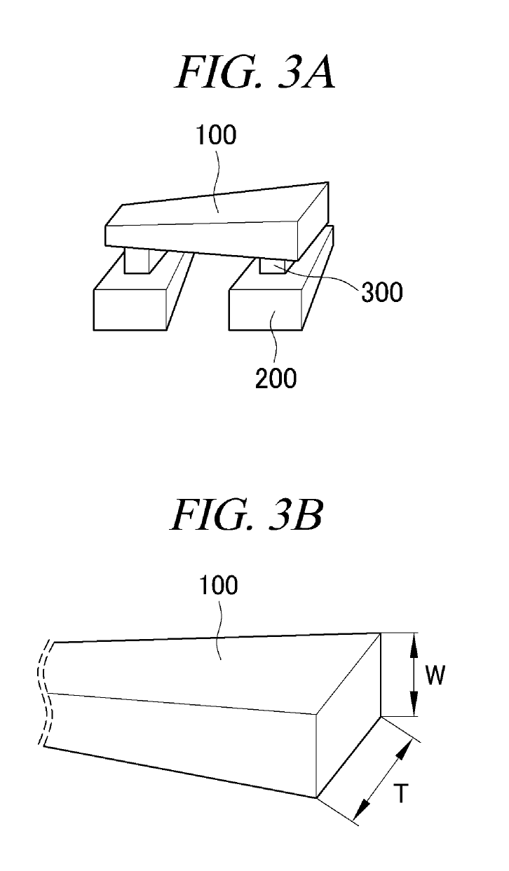

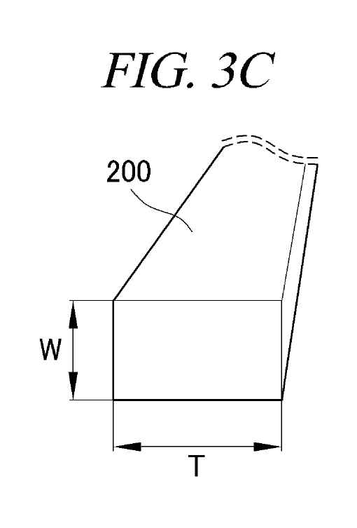

The cross-point memory cells 300 are located at cross-points between the word lines 100 and the bit lines and thus can be seen more clearly from FIG. 3.

FIG. 3A to FIG. 3C provide perspective views of a cross-point memory cell in accordance with an exemplary embodiment of the present disclosure.

As illustrated in FIG. 3A, the cross-point memory cell 300 is located and electrically connected between the word line 100 and the bit line 200.

Although not illustrated in the drawings, components of the cross-point memory device 10 may be implemented on a substrate. The substrate may be any semiconducting substrate such as monocrystalline silicon, IV-IV compounds such as silicon-germanium or silicon-germanium-carbon, III-V compounds, II-VI compounds, epitaxial layers over such substrates, or any other semiconducting or non-semiconducting material such as silicon oxide, glass, plastic, metal or ceramic substrate. The substrate may include integrated circuits fabricated thereon, such as driver circuits for a memory device.

Referring to FIG. 2 again, a set of conductive electrodes referred to as the word lines 100 in the present specification is connected in contact with upper surfaces of the memory cells 300. Each of the word lines 100 is in electrical contact with the memory cells 300 respectively located at predetermined points.

In particular, the word lines 100 may be connected to the first controller 400 to be described later and may be arranged in parallel with the second controller 500. In this case, a cross-sectional area of the word line 100 is different between points respectively spaced away from a first end of the word line 100. For example, a cross-sectional area of the word line 100 may be increased as being farther from the first end of the word line 100. However, the present disclosure is not limited thereto, and a cross-sectional area of the word line 100 may be increased stepwise. Otherwise, a cross-sectional area of the word line 100 may be gradually increased in a certain region, then may remain constant and then may be increased again.

In FIG. 2, a cross-sectional area of the word line 100 is increased as being farther from the first controller 400 located at the first end of the word line 100. Thus, a resistivity value increased in proportion to a distance between the word line 100 and the first controller 400 can be adjusted. Such a change in cross-sectional area may include a change in width W or a change in thickness T. To be more specific, widths or thicknesses of the word lines 100 may be increased as being farther from the first end of the word lines 100.

For reference, the term “cross-sectional area” used herein means a cross-sectional area of a cross-section perpendicular to a longitudinal direction of the word lines. Referring to FIG. 3B, a change in cross-sectional area may include a change in width W or a change in thickness T.

Further, the first end of the word line 100 may mean an end of the word line 100 as a connection portion between the word line 100 and the first controller 400.

Meanwhile, a set of conductive electrodes referred to as the bit lines 200 in the present specification is connected in contact with lower surfaces of the memory cells 300. Each of the bit lines 200 is in electrical contact with the memory cells 300 respectively located at predetermined points.

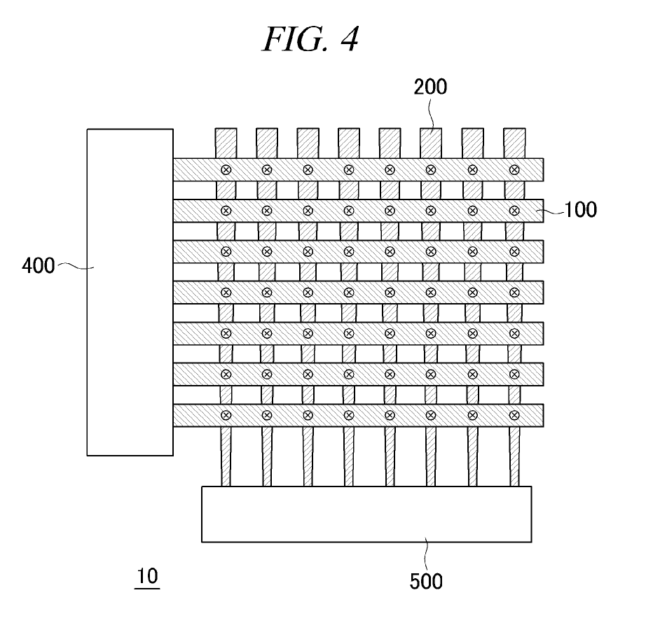

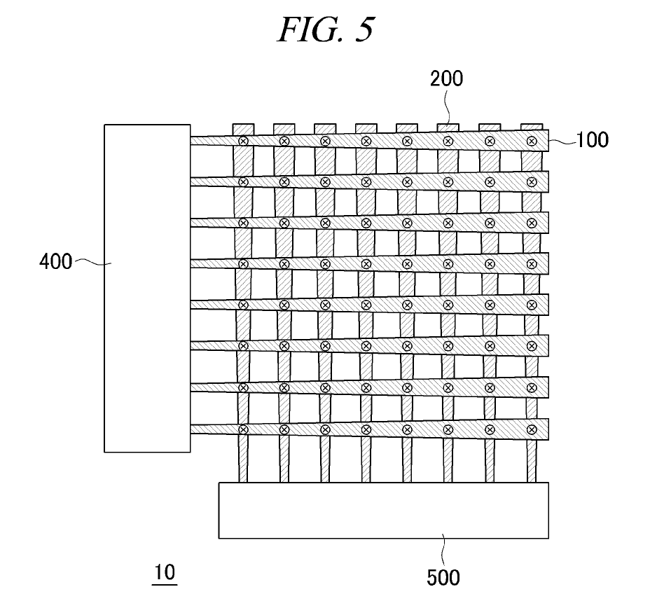

In particular, the bit lines 200 may be connected to the second controller 500 to be described later and may be arranged in parallel with the first controller 400. FIG. 2 illustrates a case where a resistivity value occurring in the word line 100 is adjusted by adjusting only a cross-sectional area of the word line 100. However, exemplary embodiments of the present disclosure are not limited thereto, and the resistivity value may be adjusted by adjusting a cross-sectional area of the bit line 200. Details thereof will be described with reference to FIG. 4 and FIG. 5.

Further, a delay time occurring in the word line 100 and the bit line 200 depending on a cross-sectional area can be explained according to the following Equation.

$$τ = {\sum }_{j = 1}^{N} {C}_{j} {\sum }_{k = 1}^{j} {R}_{k} \qquad [ Equation ]$$

Cⱼ and Rₖ represent a capacitance and a resistivity value of each conductor when a conductor is equally divided into N number of conductors. Herein, a difference in delay time can be adjusted by increasing the cross-sectional area and reducing the resistivity value of the conductor.

Meanwhile, the memory cell 300 may include a resistive memory element such as a memristor, a phase change material resistor, a conductive bridge resistor, a transition metal oxide-based resistor, and any embodiment of resistive changing memory.

Each memory cell 300 is placed at a cross-point between one word line 100 and one bit line 200 involved in the memory cell 300. Each memory cell 300 may be selected to write or read by activating specific word line 100 and bit line 200 involved in the memory cell 300.

The cross-point memory device 10 includes the first controller 400 connected to the memory cells 300 through the respective word lines 100 and configured to activate a specific word line 100 in order to read or write a specific memory cell 300 involved in the word line 100. For example, the first controller 400 may include a row decoder to select a specific word line 100 from among the word lines 100, and a multiplexer.

The cross-point memory device 10 includes the second controller 400 connected to the memory cells 300 through the respective bit lines 200. The second controller 500 may include a memory sense amplifier, a write driver, a demultiplexer, and an input/output pad.

The first controller 400 and the second controller 500 operate in cooperation with each other to access each selected memory cell 300 by activating the corresponding word line 100 and bit line 200 connected to the selected memory cell 300. Another configuration known to those skilled in the art may be used to access the memory cells 300 according to the present disclosure.

During a writing operation, the first controller 400 applies a voltage to a specific word line 100 corresponding to a selected memory cell 300 to write information in the selected memory cell 300. The second controller 500 connects the memory cell 300 to the ground and thus activates the selected memory cell 300. Then, a current flows through the selected memory cell 300 and affects the characteristics of the memory cell 300. Actually, a logic 1 or logic 0 is stored in the memory cell 300. For example, if a memory element included in the memory cell 300 is a memristor, a current flowing through the memristor changes a resistivity of the memristor. Such a change in resistivity may be detected during a subsequent reading operation.

During the reading operation, the first controller 400 activates the selected memory cell 300 by applying a predetermined voltage to the corresponding word line 100, and the second controller 500 accesses the bit line 200 corresponding to the selected memory cell 300. A resultant current detected by the second controller 500 indicates a state of the memory cell, e.g., whether the memory cell 300 corresponds to the logic 1 or the logic 0.

Meanwhile, an active region may be arranged under the bit lines 200.

Further, as illustrated in FIG. 1A and FIG. 1B, in this memory structure, the word lines may be typically located on top or the bit lines may be located on top.

FIG. 4 is an exemplary diagram of a cross-point memory device in accordance with another exemplary embodiment of the present disclosure.

The cross-point memory device 10 in accordance with another exemplary embodiment of the present disclosure may include the multiple word lines 100 arranged in parallel with each other and the multiple bit lines 200 arranged to be orthogonal to the word lines 100 and parallel with each other. Further, although not illustrated in the drawing, multiple cross-point memory cells electrically connected between the word lines 100 and the bit lines 200, the first controller 400 connected to the word lines 100 and arranged on a first side of the word lines 100, and the second controller 500 connected to the bit lines 200 and arranged on a first side of the bit lines 200 are also included.

Herein, FIG. 4 illustrates that the word line 100 has a constant cross-sectional area but a cross-sectional area of the bit line 200 is different between points respectively spaced away from the first end of the bit line 200. For example, a cross-sectional area of the bit line 200 may be increased as being farther from the first end of the bit line 200. However, the present disclosure is not limited thereto, and a cross-sectional area of the bit line 200 may be increased stepwise. Otherwise, a cross-sectional area of the bit line 200 may be gradually increased in a certain region, then may remain constant and then may be increased again.

Typically, a resistivity of the bit line 200 is increased as being farther from the second controller 500 located at the first end of the bit line 200 and thus increased in proportion to a distance between the bit line 200 and the second controller 500. Thus, a resistivity value of a corresponding point can be adjusted by adjusting a cross-sectional area of the bit line 200. Such a change in cross-sectional area may include a change in width or a change in thickness. To be more specific, widths or thicknesses of the bit lines 200 may be increased as being farther from the first end of the bit lines 200.

For reference, the term “cross-sectional area” used herein means a cross-sectional area of a cross-section perpendicular to a longitudinal direction of the bit lines 200. Referring to FIG. 3C, a change in cross-sectional area may include a change in width W or a change in thickness T.

Further, the first end of the bit line 200 may mean an end of the bit line 200 as a connection portion between the bit line 200 and the second controller 500.

That is, a width of the bit line 200 is formed to be increased as being farther from the second controller 500, or a thickness of the bit line 200 is formed to be increased as being farther from the second controller 500.

Further, as illustrated in FIG. 1A and FIG. 1B, in this memory structure, the word lines 100 may be typically located on top or the bit lines 200 may be located on top.

FIG. 5 is an exemplary diagram of a cross-point memory device in accordance with another exemplary embodiment of the present disclosure.

The cross-point memory device 10 in accordance with another exemplary embodiment of the present disclosure may include the multiple word lines 100 arranged in parallel with each other and the multiple bit lines 200 arranged to be orthogonal to the word lines 100 and parallel with each other. Further, although not illustrated in the drawing, multiple cross-point memory cells electrically connected between the word lines 100 and the bit lines 200, the first controller 400 connected to the word lines 100 and arranged on the first side of the word lines 100, and the second controller 500 connected to the bit lines 200 and arranged on the first side of the bit lines 200 are also included.

In some cases, locations of the respective controllers may be changed from the first sides to the other sides, and directions are not limited to those illustrated in the drawing as long as there is no change in connection to the word lines 100 and the bit lines 200.

Herein, FIG. 5 illustrates a case where a cross-sectional area of the word line 100 and a cross-sectional area of the bit line 200 area changed. That is, it can be seen that a cross-sectional area of the bit line 200 and a cross-sectional area of the word line 100 are different depending on distances from their respective ends as described above. A cross-sectional area of each of the word line 100 and the bit line 200 is increased in proportion to a distance from a reference controller. Thus, a resistivity value can be adjusted. Further, such a change in cross-sectional area may include a change in width or a change in thickness.

Further, as illustrated in FIG. 1A and FIG. 1B, in this memory structure, the word lines 100 may be typically located on top or the bit lines 200 may be located on top.

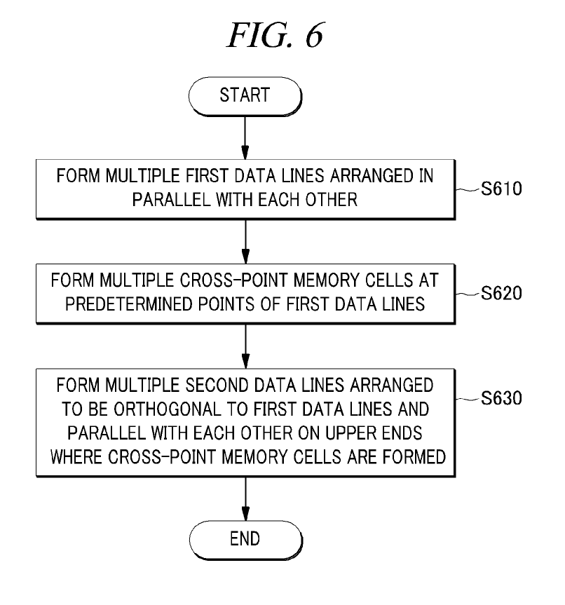

Meanwhile, FIG. 6 is a flowchart showing a method of manufacturing a cross-point memory device in accordance with an exemplary embodiment of the present disclosure.

A method of manufacturing the cross-point memory device 10 in accordance with an exemplary embodiment of the present disclosure may include forming multiple first data lines 200 arranged in parallel with each other (S610), forming multiple cross-point memory cells 300 at predetermined points of the first data lines (S620), and forming multiple second data lines 100 arranged to be orthogonal to the first data lines 200 and parallel with each other on upper ends where the cross-point memory cells 300 are formed (S630).

If the cross-point memory device 10 in accordance with an exemplary embodiment of the present disclosure is implemented as illustrated in FIG. 2, a cross-sectional area of a cross-section perpendicular to the longitudinal direction of the word lines 100 is formed to be increased as being farther from the first end of the word lines 100 in S630. In this case, the bit lines 200 are formed to have a constant thickness and to be in parallel with each other (S610).

Further, in a case illustrated in FIG. 4, a cross-sectional area of a cross-section perpendicular to the longitudinal direction of the bit lines 200 is formed to be increased as being farther from the first end of the bit lines 200 in S610. In this case, the word lines 100 are formed to have a constant thickness and to be in parallel with each other (S630).

In a case illustrated in FIG. 5, a cross-sectional area of a cross-section perpendicular to the longitudinal direction of the bit lines 200 is formed to be increased as being farther from the first end of the bit lines 200 in S610, and a cross-sectional area of a cross-section perpendicular to the longitudinal direction of the word lines 100 is formed to be increased as being farther from the first end of the word lines 100 in S630.

That is, in the case illustrated in FIG. 5, a cross-sectional area of a cross-section perpendicular to the longitudinal direction of the word lines 100 may be formed to be increased as being farther from the first end of the word lines 100 and a width of the word lines 100 may be formed to be increased as being farther from the first end of the word lines 100, and likewise, a cross-sectional area of a cross-section perpendicular to the longitudinal direction of the bit lines 200 may be formed to be increased as being farther from the first end of the bit lines 200 and a width of the bit lines 200 may be formed to be increased as being farther from the first end of the bit lines 200.

Each component may be manufactured three-dimensionally on a monocrystalline silicon substrate through generally known semiconductor manufacturing processes such as thin film deposition, lithography, etching, packaging, and the like.

Hereinafter, a structure in which first data lines or second data lines are alternately arranged will be described.

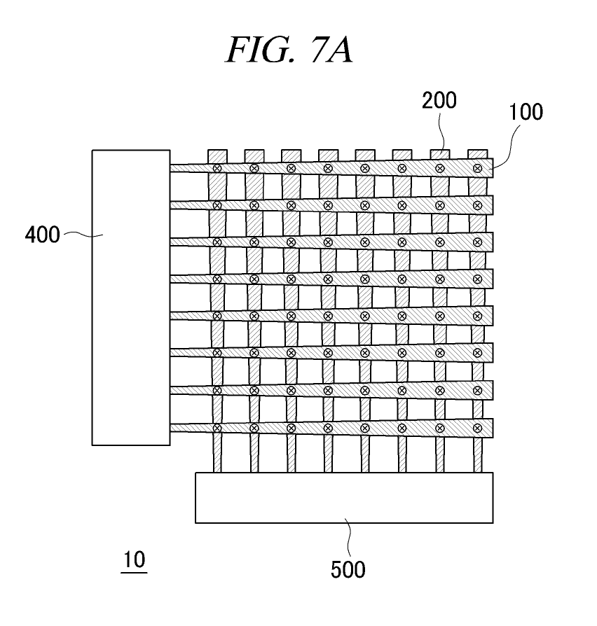

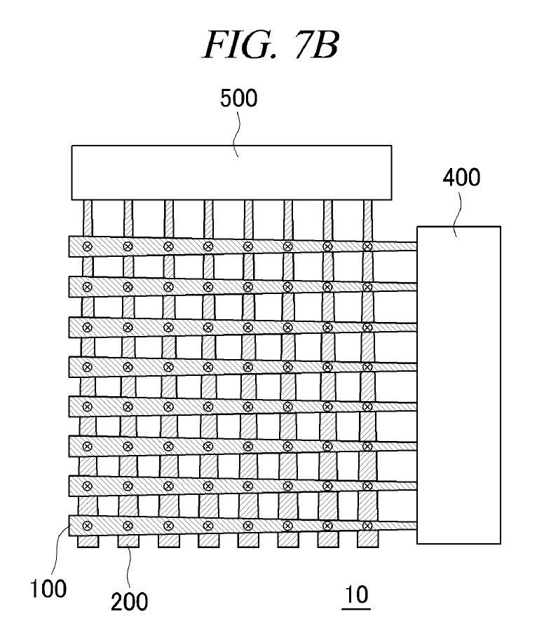

As illustrated in FIG. 7A to FIG. 10B, the first data lines include a first group of first data lines arranged in parallel with each other and a second group of first data lines arranged in parallel with each other between the first data lines of the first group. Further, the second data lines include a first group of second data lines arranged in parallel with each other and a second group of second data lines arranged in parallel with each other between the second data lines of the first group.

FIG. 7A and FIG. 7B provide exemplary diagrams illustrating components of a cross-point memory device in accordance with another exemplary embodiment of the present disclosure. FIG. 7A and FIG. 7B illustrate components of the cross-point memory device, respectively. FIG. 7B is a view obtained by rotating FIG. 7A 180 degrees clockwise to more clearly explain an exemplary embodiment of the present disclosure.

The cross-point memory device is in a state where the structures illustrated in FIG. 7A and FIG. 7B are overlapped. The word lines illustrated in FIG. 7B may be arranged between the word lines illustrated in FIG. 7A, or the bit lines illustrated in FIG. 7B may be arranged between the bit lines illustrated in FIG. 7A.

In this case, a cross-sectional area of the word line 100 is formed to be different between points respectively spaced away from the first end. For example, a cross-sectional area of the word line 100 may be formed to be increased as being farther from the first end of the word lines 100. However, the present disclosure is not limited thereto, and a cross-sectional area of the word line 100 may be increased stepwise. Otherwise, a cross-sectional area of the word line 100 may be gradually increased in a certain region, then may remain constant and then may be increased again.

Likewise, a cross-sectional area of the bit line 200 is formed to be different between points respectively spaced away from the first end of the bit lines 200. For example, a cross-sectional area of the bit line 200 may be formed to be increased as being farther from the first end of the bit lines 200. However, the present disclosure is not limited thereto, and a cross-sectional area of the bit line 200 may be increased stepwise. Otherwise, a cross-sectional area of the bit line 200 may be gradually increased in a certain region, then may remain constant and then may be increased again.

In FIG. 7A and FIG. 7B, a cross-sectional area of the word line 100 is increased as being farther from the first controller 400 located at an end on a first side of the word lines 100. Thus, a resistivity value increased in proportion to a distance between the word line 100 and the first controller 400 can be adjusted.

Likewise, the bit lines 200 may be connected to the second controller 500 to be described later and may be arranged in parallel with the first controller 400. In this case, it can be seen that a cross-sectional area of the bit line 200 is formed to be increased as being farther from an end on a first side of the bit lines 200. Herein, the first side refers to a lower side on the drawing.

Herein, a cross-sectional area of the bit line 200 is increased as being farther from the second controller 500 located on the first side of the bit lines 200. Thus, a resistivity value increased in proportion to a distance between the bit line 200 and the second controller 500 can be adjusted.

Such a change in cross-sectional area may include a change in width W or a change in thickness T. That is, widths or thicknesses of the word lines 100 may be increased as being farther from the end on the first side of the word lines 100, and widths or thicknesses of the bit lines 200 may be increased as being farther from the end on the first side of the bit lines 200.

Further, the end on the first side of the word line 100 may mean an end of the word line 100 as a connection portion between the word line 100 and the first controller 400, and the end on the first side of the bit line 200 may mean an end of the bit line 200 as a connection portion between the bit line 200 and the second controller 500.

Further, a set of conductive electrodes referred to as the bit lines 200 in the present specification is connected in contact with lower surfaces of the memory cells 300. Each of the bit lines 200 is in electrical contact with the memory cells 300 respectively located at predetermined points.

Meanwhile, according to an exemplary embodiment of the present disclosure, by overlapping the structures illustrated in FIG. 7A and FIG. 7B, the word lines illustrated in FIG. 7B are located between the word lines illustrated in FIG. 7A and the bit lines illustrated in FIG. 7B are arranged between the bit lines illustrated in FIG. 7A. Thus, a cross-sectional area of the word lines 100 illustrated in FIG. 7A and FIG. 7B is formed to be different depending on a distance from the first controller 400 located at the end on the first side of the word lines 100 and a cross-sectional area of the bit lines 200 is formed to be different depending on a distance from the second controller 500 located at the end on the first side of the bit lines 200.

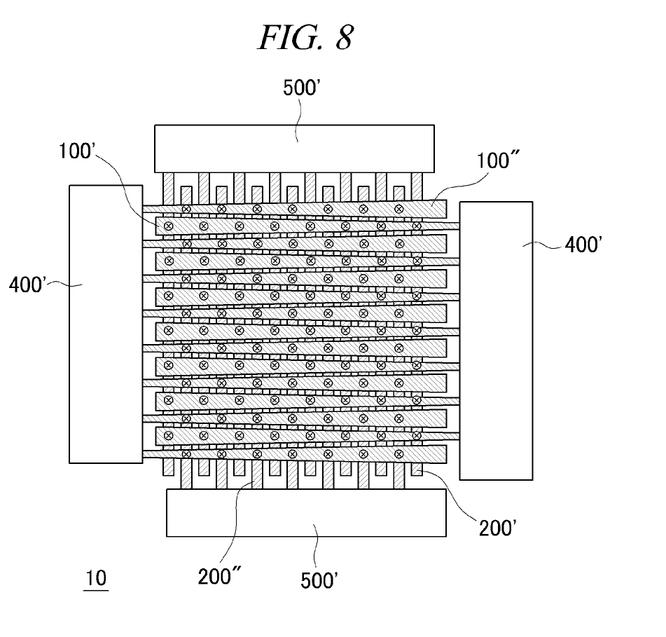

FIG. 8 is an exemplary diagram of a cross-point memory device in accordance with another exemplary embodiment of the present disclosure.

The cross-point memory device 10 in accordance with another exemplary embodiment of the present disclosure may include multiple first word lines 100′ arranged in parallel with each other, multiple second word lines 100″ arranged in parallel with each other between the first word lines 100′, multiple first bit lines 200′ arranged to be orthogonal to the first word lines 100′ and parallel with each other, multiple second bit lines 200″ arranged in parallel with each other between the first bit lines 200′, and multiple cross-point memory cells electrically connected between the first word lines 100′ and the first bit lines 200′ and between the second word lines 100″ and the second bit lines 200″.

Herein, it can be seen from FIG. 8 that the bit lines 200′ and 200″ have constant cross-sectional areas but cross-sectional areas of the word lines 100′ and 100″ are adjusted. That is, it can be seen that a cross-sectional area of a cross-section perpendicular to a longitudinal direction of the first word lines 100′ is formed to be different depending on a distance from an end on a first side of the first word lines 100′ and a cross-sectional area of a cross-section perpendicular to a longitudinal direction of the second word lines 100″ is formed to be different depending on a distance from an end on a second side of the second word lines 100″.

For reference, the first side described in the specification refers to a left side on the drawing, and the second side refers to a right side on the drawing.

Typically, a resistivity of the first word line 100′ is increased as being farther from a first controller 400′ located at the end on the first side of the first word lines 100′ and thus increased in proportion to a distance between the first word line 100′ and the first controller 400′. Thus, a resistivity value of a corresponding point can be adjusted by adjusting a cross-sectional area of the first word line 100′.

Further, a resistivity of the second word line 100″ is increased as being farther from a third controller 400″ located at the end on the second side of the second word lines 100″ and thus increased in proportion to a distance between the second word line 100″ and the third controller 400″. Thus, a resistivity value of a corresponding point can be adjusted by adjusting a cross-sectional area of the second word line 100″. Herein, the third controller 400″ has the same function as the first controller 400′ but is distinguished as the third controller 400″ for convenience.

Meanwhile, such a change in cross-sectional area may include a change in width or a change in thickness of each data line. That is, widths or thicknesses of the word lines 100 may be increased as being farther from the end on the first side of the word lines 100, and widths or thicknesses of the bit lines 200 may be increased as being farther from the end on the first side of the bit lines 200.

Further, the ends on the first side and the second side of the first and second word lines 100′ and 100″ may respectively mean ends of the first and second word lines 100′ and 100″ as connection portions between the first and second word lines 100′ and 100″ and the first and third controllers 400′ and 400″.

That is, a width or thickness of the first word line 100′ is formed to be increased as being farther from the first controller 400′ and a width or thickness of the second word line 100″ is formed to be increased as being farther from the third controller 400″.

Further, as illustrated in FIG. 1, in this memory structure, the word lines 100 may be typically located on top or the bit lines 200 may be located on top.

In some cases, locations of the respective controllers may be changed from the first sides to the other sides, and directions are not limited to those illustrated in the drawing as long as there is no change in connection to the word lines 100 and the bit lines 200.

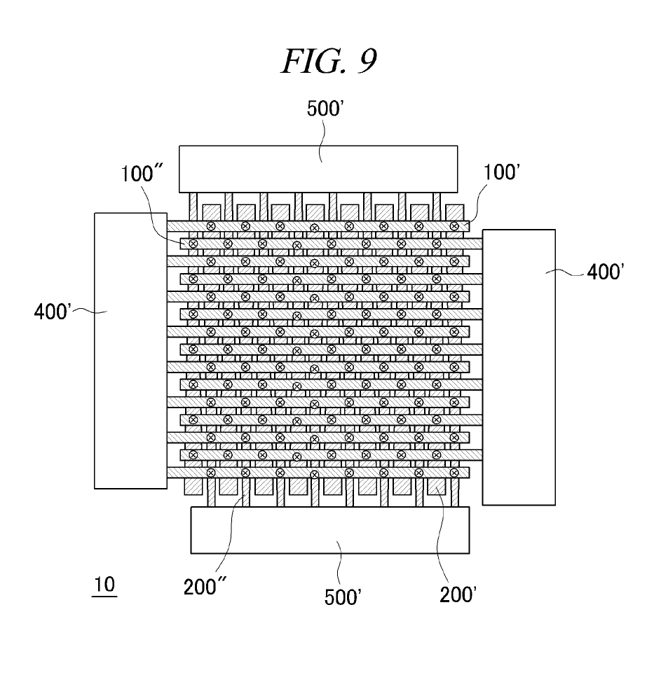

FIG. 9 is an exemplary diagram of a cross-point memory device in accordance with another exemplary embodiment of the present disclosure.

The cross-point memory device 10 in accordance with another exemplary embodiment of the present disclosure may include the multiple first word lines 100′ arranged in parallel with each other, the multiple second word lines 100″ arranged in parallel with each other between the first word lines 100′, the multiple first bit lines 200′ arranged to be orthogonal to the first word lines 100′ and parallel with each other, the multiple second bit lines 200″ arranged in parallel with each other between the first bit lines 200′, and multiple cross-point memory cells electrically connected between the first word lines 100′ and the first bit lines 200′ and between the second word lines 100″ and the second bit lines 200″.

Herein, it can be seen from FIG. 9 that the word lines 100′ and 100″ have constant cross-sectional areas but cross-sectional areas of the bit lines 200′ and 200″ are adjusted. That is, it can be seen that a cross-sectional area of a cross-section perpendicular to a longitudinal direction of the first bit lines 200′ is formed to be different depending on a distance from an end on a first side of the first bit lines 200′ and a cross-sectional area of a cross-section perpendicular to a longitudinal direction of the second bit lines 200″ is formed to be different depending on a distance from an end on a second side of the second bit lines 200″.

For reference, the first side described in the specification refers to a lower side on the drawing, and the second side refers to an upper side on the drawing.

Typically, a resistivity of the first bit line 100′ is increased as being farther from a second controller 500′ located at the end on the first side of the first bit lines 200′ and thus increased in proportion to a distance between the first bit line 200′ and the second controller 500′. Thus, a resistivity value of a corresponding point can be adjusted by adjusting a cross-sectional area of the first bit line 200′.

Further, a resistivity of the second bit line 200″ is increased as being farther from a fourth controller 500″ located at the end on the second side of the second bit lines 200″ and thus increased in proportion to a distance between the second bit line 200″ and the fourth controller 500″. Thus, a resistivity value of a corresponding point can be adjusted by adjusting a cross-sectional area of the second bit line 200″.

Meanwhile, such a change in cross-sectional area may include a change in width or a change in thickness. That is, a width W or thickness T of the first bit line 200′ may be increased as being farther from the end on the first side and a width or thickness of the second bit line 200″ may be increased as being farther from the end of the second side.

Further, the ends on the first side and the second side of the first and second bit lines 200′ and 200″ may respectively mean ends of the first and second bit lines 200′ and 200″ as connection portions between the first and second bit lines 200′ and 200″ and the second and fourth controllers 500′ and 500″.

That is, a width or thickness of the first bit line 200′ is formed to be increased as being farther from the second controller 500′ and a width or thickness of the second bit line 200″ is formed to be increased as being farther from the fourth controller 500″.

Further, as illustrated in FIG. 1A and FIG. 1B, in this memory structure, the word lines 100 may be typically located on top or the bit lines 200 may be located on top.

In some cases, locations of the respective controllers may be changed from the first sides to the other sides, and directions are not limited to those illustrated in the drawing as long as there is no change in connection to the word lines 100 and the bit lines 200.

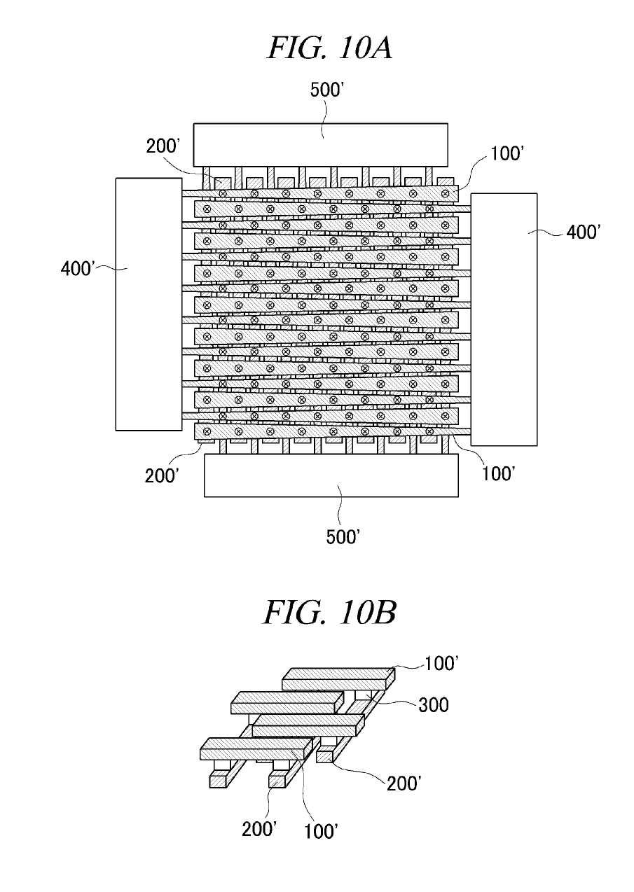

FIG. 10A and FIG. 10B provide configuration views of a cross-point memory device in accordance with another exemplary embodiment of the present disclosure.

FIG. 10A is a view obtained by overlapping the structures illustrated in FIG. 7A and FIG. 7B, and FIG. 10B is a perspective view of FIG. 10A.

The cross-point memory device 10 in accordance with an exemplary embodiment of the present disclosure may include the multiple first word lines 100′ arranged in parallel with each other, the multiple second word lines 100″ arranged in parallel with each other between the first word lines 100′, the multiple first bit lines 200′ arranged to be orthogonal to the first word lines 100′ and parallel with each other, the multiple second bit lines 200″ arranged in parallel with each other between the first bit lines 200′, and multiple cross-point memory cells 300 electrically connected between the first word lines 100′ and the first bit lines 200′ and between the second word lines 100″ and the second bit lines 200″.

In this case, a cross-sectional area of a cross-section perpendicular to the longitudinal direction of the first bit lines 200′ is formed to be increased as being farther from the end on the first side of the first bit lines 200′ and a cross-sectional area of a cross-section perpendicular to the longitudinal direction of the second bit lines 200″ is formed to be increased as being farther from the end on the second side of the second bit lines 200″.

Herein, an increase in cross-sectional area may be caused by a change in width or thickness. That is, a width of the first bit line 200′ may be increased as being farther from the end on the first side of the first bit lines 200′. Likewise, a thickness of the first bit line 200′ may be increased as being farther from the end on the first side of the first bit lines 200′.

As such, a width of the second bit line 200″ may be increased as being farther from the end on the second side of the second bit lines 200″. Likewise, a thickness of the second bit line 200″ may be increased as being farther from the end on the second side of the second bit lines 200″.

Further, a cross-sectional area of a cross-section perpendicular to the longitudinal direction of the first word lines 100′ may be formed to be increased as being farther from the end on the first side of the first word lines 100′.

As described above, an increase in cross-sectional area of the first word line 100′ may be caused by a change in width or thickness. That is, a width of the first word line 100′ may be increased as being farther from the end on the first side of the first word lines 100′. Likewise, a thickness of the first word line 100′ may be increased as being farther from the end on the first side of the first word lines 100′.

Furthermore, a cross-sectional area of a cross-section perpendicular to the longitudinal direction of the second word lines 100″ may be formed to be increased as being farther from the end on the second side of the second word lines 100″. That is, a width of the second word line 100″ may be increased as being farther from the end on the second side of the second word lines 100″. Likewise, a thickness of the second word line 100″ may be increased as being farther from the end on the second side of the second word lines 100″.

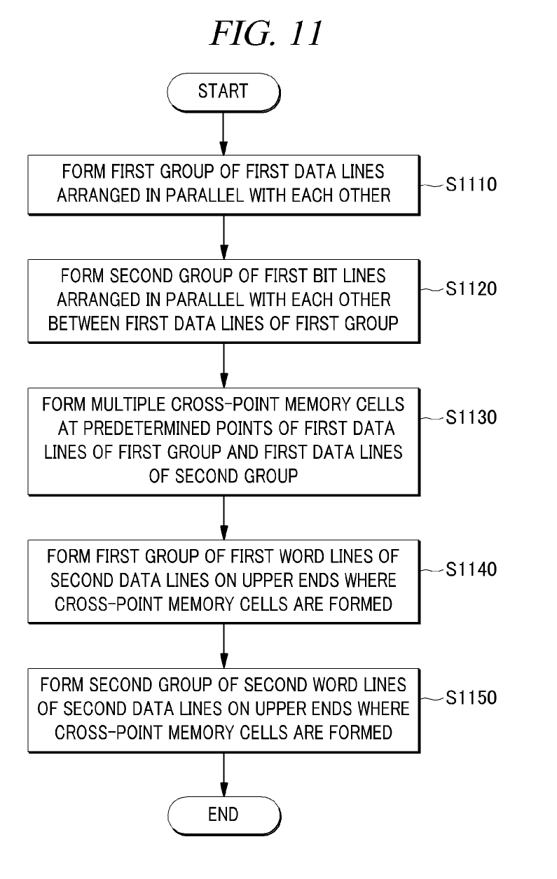

FIG. 11 is a flowchart showing a method of manufacturing a cross-point memory device in accordance with another exemplary embodiment of the present disclosure.

The method of manufacturing the cross-point memory device 10 in accordance with an exemplary embodiment of the present disclosure may include forming a first group of first data lines arranged in parallel with each other (S1110), forming a second group of first bit lines arranged in parallel with each other between the first data lines of the first group (S1120), forming multiple cross-point memory cells 300 at predetermined points of the first data lines of the first group and first data lines of a second group (S1130), forming a first group of first word lines arranged to be orthogonal to the first data lines and parallel with each other on upper ends where the cross-point memory cells 300 are formed (S1140), and forming a second group of second word lines arranged to be orthogonal to the first data lines and parallel with each other on upper ends where the cross-point memory cells 300 are formed (S1150).

If the cross-point memory device 10 in accordance with an exemplary embodiment of the present disclosure is implemented as illustrated in FIG. 10, cross-sectional areas of cross-sections perpendicular to the longitudinal directions of the first and second bit lines 200′ and 200″ and first and second word lines 100′ and 100″ are formed to be increased as being farther from the ends on the first and second sides in S1110, S1120, S1140, and S1150, respectively.

Further, in a case illustrated in FIG. 8, cross-sectional areas of cross-sections perpendicular to the longitudinal directions of the first and second word lines 100′ and 100″ are formed to be increased as being farther from the ends on the first and second sides of the first and second word lines 100′ and 100″ in S1140 and S1150. In this case, the bit lines 200 are formed to have a constant thickness and to be in parallel with each other (S1110 and S1120).

Moreover, in a case illustrated in FIG. 9, cross-sectional areas of cross-sections perpendicular to the longitudinal directions of the first and second bit lines 200′ and 200″ are formed to be increased as being farther from the ends on the first and second sides of the first and second bit lines 200′ and 200″ in S1110 and S1120. In this case, the word lines 100 are formed to have a constant thickness and to be in parallel with each other (S1140 and S1150).

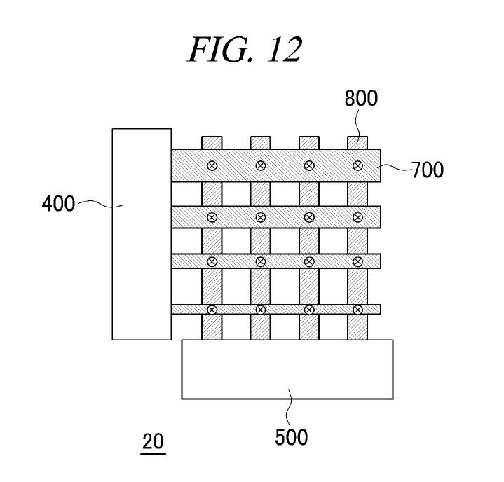

FIG. 12 is a configuration view of a cross-point memory device in accordance with another exemplary embodiment of the present disclosure.

A cross-point memory device 20 includes word lines 700, bit lines 800, cross-point memory cells 300, the first controller 400, and the second controller 500. The first controller 400 and the second controller 500 have the same configurations as those described above, and, thus, a detailed explanation thereof will be omitted.

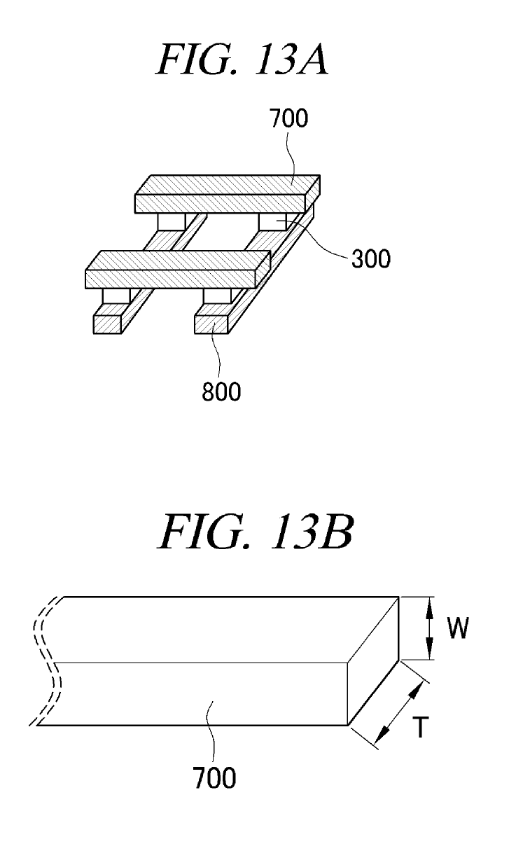

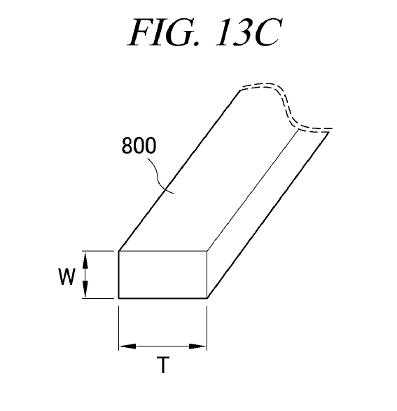

The cross-point memory cells 300 are located at cross-points between the word lines 700 and the bit lines 800 in the drawing and thus can be seen more clearly with reference to FIG. 13A to FIG. 13C.

FIG. 13A to FIG. 13C provide perspective views of a cross-point memory cell in accordance with another exemplary embodiment of the present disclosure.

As illustrated in FIG. 13A, the cross-point memory cell 300 is located and electrically connected between the word line 700 and the bit line 800.

Referring to FIG. 12 again, a set of conductive electrodes referred to as the word lines 700 in the present specification is extended on one side of the memory cells 300. Each of the word lines 700 is in electrical contact with the memory cells 300 in a specific row.

In particular, the word lines 700 may be connected to the first controller 400 and may be arranged in parallel with the second controller 500. In this case, it can be seen that cross-sectional areas of the word lines 700 are formed to be different depending on a distance from a first end of the bit lines 800. Herein, cross-sectional areas of the word lines 700 may be increased as being farther from the second controller 500 located at the first end of the bit lines 800. Thus, a resistivity value increased in proportion to a distance between the word line 700 and the controller can be adjusted. Such a change in cross-sectional area may include a change in width W or a change in thickness T. To be more specific, widths or thicknesses of the word lines 700 may be increased as being farther from the first end of the bit lines 800.

For reference, the term “cross-sectional area” used herein means a cross-sectional area of a cross-section perpendicular to a longitudinal direction of the word lines. Referring to FIG. 13B, a change in cross-sectional area may include a change in width W or a change in thickness T.

Further, the first end of the bit line 800 may mean an end of the bit line 800 as a connection portion between the bit line 800 and the second controller 500.

Meanwhile, a set of conductive electrodes referred to as the bit lines 800 in the present specification is extended on the other side of the memory cells 300. Each of the bit lines 800 is in electrical contact with the memory cells 300 in a specific row.

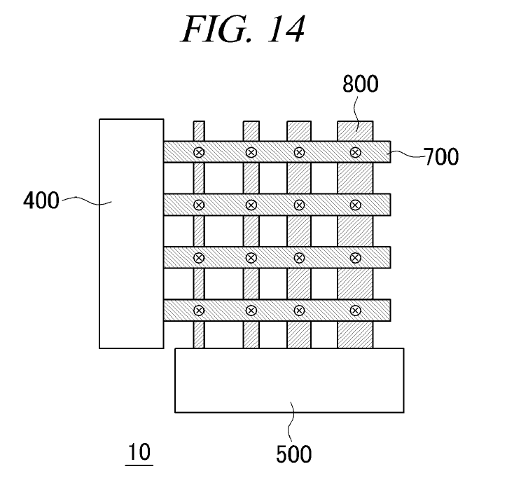

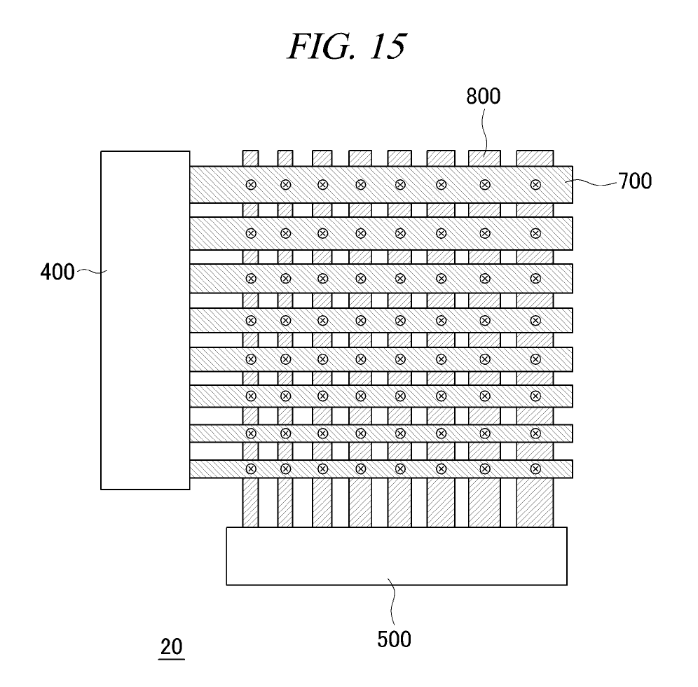

In particular, the bit lines 800 may be connected to the second controller 500 to be described later and may be arranged in parallel with the first controller 400. FIG. 12 illustrates a case where a resistivity value occurring in the word line 700 is adjusted by adjusting only a cross-sectional area of the word line 700. However, exemplary embodiments of the present disclosure are not limited thereto, and the resistivity value may be adjusted by adjusting a cross-sectional area of the bit line 800. Details thereof will be described with reference to FIG. 14 and FIG. 15.

Further, as illustrated in FIG. 1A and FIG. 1B, in this memory structure, the word lines may be typically located on top or the bit lines may be located on top.

FIG. 14 is an exemplary diagram of a cross-point memory device in accordance with another exemplary embodiment of the present disclosure.

The cross-point memory device 20 in accordance with another exemplary embodiment of the present disclosure may include the multiple word lines 700 arranged in parallel with each other and the multiple bit lines 800 arranged to be orthogonal to the word lines 700 and parallel with each other. Further, although not illustrated in the drawing, multiple cross-point memory cells electrically connected between the word lines 700 and the bit lines 800, the first controller 400 connected to the word lines 700 and arranged on a first side of the word lines 700, and the second controller 500 connected to the bit lines 800 and arranged on a first side of the bit lines 800 are also included.

Herein, it can be seen from FIG. 14 that the word lines 700 have a constant cross-sectional area but cross-sectional areas of the bit lines 800 are formed to be increased as being farther from the first end of the word lines 700. Herein, cross-sectional areas of the bit lines 800 are increased as being farther from the first controller 400 located at the first end of the word lines 700. Thus, a resistivity value increased in proportion to a distance between the bit line 800 and the controller can be adjusted. Such a change in cross-sectional area may include a change in width or a change in thickness. To be more specific, widths W or thicknesses T of the bit lines 800 may be increased as being farther from the first end of the word lines 700.

For reference, the term “cross-sectional area” used herein means a cross-sectional area of a cross-section perpendicular to a longitudinal direction of the bit lines 800. Referring to FIG. 13C, a change in cross-sectional area may include a change in width W or a change in thickness T.

Further, the first end of the word line 700 may mean an end of the word line 700 as a connection portion between the word line 700 and the first controller 400.

That is, widths of the bit lines 800 are formed to be increased as being farther from the first controller 400, and thicknesses of the bit lines 800 are formed to be increased as being farther from the first controller 400.

Further, as illustrated in FIG. 1A and FIG. 1B, in this memory structure, the word lines may be typically located on top or the bit lines may be located on top.

FIG. 15 is an exemplary diagram of a cross-point memory device in accordance with another exemplary embodiment of the present disclosure.

The cross-point memory device 10 in accordance with another exemplary embodiment of the present disclosure may include the multiple word lines 700 arranged in parallel with each other and the multiple bit lines 800 arranged to be orthogonal to the word lines 700 and parallel with each other. Further, although not illustrated in the drawing, multiple cross-point memory cells electrically connected between the word lines 700 and the bit lines 800, the first controller 400 connected to the word lines 700 and arranged on the first side of the word lines 700, and the second controller 500 connected to the bit lines 800 and arranged on the first side of the bit lines 800 are also included.

In some cases, locations of the respective controllers may be changed from the first sides to the other sides, and directions are not limited to those illustrated in the drawing as long as there is no change in connection to the word lines 700 and the bit lines 800.

Herein, FIG. 15 illustrates a case where cross-sectional areas of the word lines 700 and cross-sectional areas of the bit lines 800 area changed. That is, it can be seen that cross-sectional areas of the bit lines 800 are formed to be increased as being farther from the first end of the word lines 700 as described above. Likewise, it can be seen that cross-sectional areas of the word lines 700 are formed to be increased as being farther from the first end of the bit lines 800. Cross-sectional areas of each of the word lines 700 and the bit lines 800 are increased in proportion to a distance from a reference controller. Thus, a resistivity value can be adjusted. Further, such a change in cross-sectional area may include a change in width or a change in thickness.

Further, as illustrated in FIG. 1A and FIG. 1B, in this memory structure, the word lines may be typically located on top or the bit lines may be located on top.

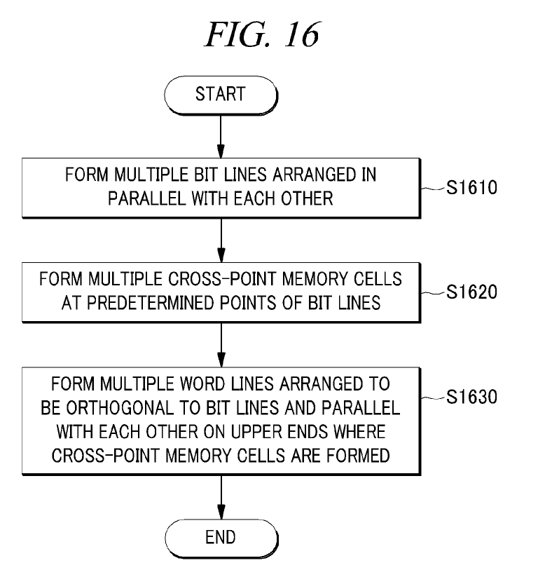

Meanwhile, FIG. 16 is a flowchart showing a method of manufacturing a cross-point memory device in accordance with another exemplary embodiment of the present disclosure.

A method of manufacturing a cross-point memory device in accordance with an exemplary embodiment of the present disclosure may include forming multiple first data lines arranged in parallel with each other (S1610), forming multiple cross-point memory cells 300 at predetermined points of the first data lines (S1620), and forming multiple second data lines arranged to be orthogonal to the first data lines and parallel with each other on upper ends where the cross-point memory cells 300 are formed (S1630).

In this case, cross-sectional areas of cross-sections perpendicular to a longitudinal direction of the second data lines are formed to be increased as being farther from a first end of the first data lines (FIG. 12).

The above description of the present disclosure is provided for the purpose of illustration, and it would be understood by those skilled in the art that various changes and modifications may be made without changing technical conception and essential features of the present disclosure. Thus, it is clear that the above-described examples are illustrative in all aspects and do not limit the present disclosure. For example, each component described to be of a single type can be implemented in a distributed manner. Likewise, components described to be distributed can be implemented in a combined manner.

The scope of the present disclosure is defined by the following claims rather than by the detailed description of the embodiment. It shall be understood that all modifications and embodiments conceived from the meaning and scope of the claims and their equivalents are included in the scope of the present disclosure. While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A cross-point memory device comprising:
multiple first data lines arranged in parallel with each other;
multiple second data lines arranged to intersect with the first data lines and arranged in parallel with each other; and
multiple cross-point memory cells electrically connected between the first data lines and the second data lines, respectively,
wherein the first data line spaced away by a first distance from an end of the first data lines has a different cross-sectional area from the first data line spaced away by a second distance from the end of the first data lines, and
the cross-sectional area of the first data line is a cross-sectional area at a cross-point with respect to the second data line.

2. The cross-point memory device of claim 1, wherein the first data lines and the second data lines are word lines or bit lines, and.
if the first data lines are word lines, the second data lines are bit lines, and if the first data lines are bit lines, the second data lines are word lines.

3. The cross-point memory device of claim 1, wherein cross-sectional areas of the first data lines are formed to be increased as being farther from the end of the first data lines.

4. The cross-point memory device of claim 3, wherein widths or thicknesses of the first data lines are increased as being farther from the end of the first data lines.

5. The cross-point memory device of claim 1, wherein the second data line spaced away by a first distance from an end of the second data lines has a different cross-sectional area from the second data line spaced away by a second distance from the end of the second data lines, and
the cross-sectional area of the second data line is a cross-sectional area at a cross-point with respect to the first data line.

6. The cross-point memory device of claim 5, wherein cross-sectional areas of the second data lines are formed to be increased as being farther from the end of the second data lines.

7. The cross-point memory device of claim 6, wherein widths or thicknesses of the second data lines are increased as being farther from the end of the second data lines.

8. The cross-point memory device of claim 1, wherein the first data lines include a first group of first data lines arranged in parallel with each other and a second group of first data lines arranged in parallel with each other between the first data lines of the first group,
the first data line of the first group spaced away by a first distance from an end of the first data lines of the first group has a different cross-sectional area from the first data line of the first group spaced away by a second distance from the end of the first data lines of the first group,
the first data line of the second group spaced away by a first distance from an end of the first data lines of the second group has a different cross-sectional area from the first data line of the second group spaced away by a second distance from the end of the first data lines of the second group, and
the cross-sectional area of the first data line is a cross-sectional area at a cross-point with respect to the second data line.

9. The cross-point memory device of claim 8, wherein cross-sectional areas of the first data lines of the first group are formed to be increased as being farther from an end on a first side of the first data lines of the first group, and
cross-sectional areas of the first data lines of the second group are formed to be increased as being farther from an end on a second side of the first data lines of the second group.

10. The cross-point memory device of claim 9, wherein widths or thicknesses of the first data lines of the first group are increased as being farther from the end on the first side of the first data lines of the first group, and
widths or thicknesses of the first data lines of the second group are increased as being farther from the end on the second side of the first data lines of the second group.

11. The cross-point memory device of claim 8, wherein the second data lines include a first group of second data lines arranged in parallel with each other and a second group of second data lines arranged in parallel with each other between the second data lines of the first group,
the second data line of the first group spaced away by a first distance from an end of the second data lines of the first group has a different cross-sectional area from the second data line of the first group spaced away by a second distance from the end of the second data lines of the first group,
the second data line of the second group spaced away by a first distance from an end of the second data lines of the second group has a different cross-sectional area from the second data line of the second group spaced away by a second distance from the end of the second data lines of the second group, and
the cross-sectional area of the second data line is a cross-sectional area at a cross-point with respect to the first data line.

12. The cross-point memory device of claim 11, wherein cross-sectional areas of the second data lines of the first group are formed to be increased as being farther from an end on a first side of the second data lines, and
cross-sectional areas of the second data lines of the second group are formed to be increased as being farther from an end on a second side of the second data lines.

13. The cross-point memory device of claim 12, wherein widths or thicknesses of the second data lines of the first group are increased as being farther from the end on the first side of the second data lines of the first group, and
widths or thicknesses of the second data lines of the second group are increased as being farther from the end on the second side of the second data lines of the second group.

14. A cross-point memory device comprising:
multiple first data lines arranged in parallel with each other;
multiple second data lines arranged to intersect with the first data lines and arranged in parallel with each other; and
multiple cross-point memory cells electrically connected between the first data lines and the second data lines, respectively,
wherein the second data line intersecting with an n^{th} (n is a natural number) data line of the first data lines has a different cross-sectional area from the second data line intersecting with an m^{th} (m is a natural number) data line of the first data lines.

15. The cross-point memory device of claim 14, wherein the first data lines and the second data lines are word lines or bit lines, and.
if the first data lines are word lines, the second data lines are bit lines, and if the first data lines are bit lines, the second data lines are word lines.

16. The cross-point memory device of claim 14, wherein cross-sectional areas of the second data lines are formed to be increased as being farther from an end of the first data lines.

17. The cross-point memory device of claim 16, wherein widths or thicknesses of the second data lines are increased as being farther from the end of the first data lines.

18. The cross-point memory device of claim 14, wherein the first data line intersecting with a p^{th} (p is a natural number) data line of the second data lines has a different cross-sectional area from the first data line intersecting with a q^{th} (q is a natural number) data line of the second data lines.

19. The cross-point memory device of claim 18, wherein cross-sectional areas of the first data lines are formed to be increased as being farther from a first end of the second data lines.

20. The cross-point memory device of claim 19, wherein widths or thicknesses of the first data lines are increased as being farther from the first end of the second data lines.
